(19) United States
(12) Patent Application Publication
(10) Pub. No.: US 2011/0227163 A1
(43) Pub. Date: Sep. 22, 2011

(54) SEMICONDUCTOR DEVICE

(75) Inventors: Wengwu Wang, Beijing (CN); Shijie Chen, Beijing (CN); Kai Han, Beijing (CN); Xiaolei Wang, Beijing (CN); Dapeng Chen, Beijing (CN)

(73) Assignee: INSTITUTE OF MICROELECTRONICS, CHINESE ACADEMY OF SCIENCES, BEIJING (CN)

(21) Appl. No.: 13/061,555

(22) PCT Filed: Jun. 23, 2010
(86) PCT No.: PCT/CN10/74294

§ 371 Date: Mar. 1, 2011

(30) Foreign Application Priority Data
Dec. 21, 2009 (CN) 200910242800.3
Jun. 23, 2010 (CN) PCT/CN2010/074294

(51) Int. Cl. H01L 27/092

(52) U.S. Cl. 257/369; 257/E27.062

(57) ABSTRACT

The present invention relates to a semiconductor device. Interface layers of different thickness or different materials are used in the NMOS region and the PMOS region of the semiconductor substrate, which not only effectively reduce EOT of the device, especially EOT of the PMOS device, but also increase the electron mobility of the device, especially the electron mobility of the NMOS device, thereby effectively improving the overall performance of the device.

### FIELD OF THE INVENTION

The present invention relates to a semiconductor device, particularly, to a high-k gate dielectric CMOS device with optimized interface.

### DESCRIPTION OF THE PRIOR ART

With the development of semiconductor technologies, integrated circuits having higher performance and more powerful function require higher density of elements, meanwhile, the dimension, size and space between the respective components or elements or of the respective elements per se need to be further reduced. The application of the core technology of 32/22 nanotechnology integrated circuit has become a natural trend of development in integrated circuits, and it is also one of the issues that major international semiconductor companies and research organizations race to research and develop. The CMOS device gate engineering with the “high-k/metal gate” technology as its core is the most representative core technique in 32/22 nanotechnology, and researches concerning the relevant materials, techniques and structure of the “high-k/metal gate” technology have been widely in progress.

With respect to an MOS device having a high-k/metal gate structure, the quality of the high-k gate dielectric thin film and the associated interface characteristics directly affect the electrical characteristics of the device, especially the Equivalent Oxide Thickness (EOT) and the channel carrier mobility of the device. As far as the current researches about reduction of EOT is concerned, a usual method is to optimize the material system of the gate dielectric so as to increase the dielectric constant of the high-k gate dielectric material and to reduce the thickness of the low dielectric constant interface layer between the high-k gate dielectric and the semiconductor substrate. But a problem brought about by the method is that some atoms in the high-k gate dielectric material will diffuse through the super-thin interface layer into the channel region in the semiconductor substrate under high temperature thermal processing with the continuous reduction in the thickness of the interface layer, which degrades the carrier mobility in the channel region. Besides, the degradation of the carrier mobility caused by the diffusion of the atoms in the high-k gate dielectric is more serious with an NMOS device than with a PMOS device. Moreover, in the prior art, SiON_{X} with a relative large dielectric constant is often used for the interface layer, which brings about a problem that the introduction of N from the interface layer will degrade the carrier mobility, especially the electron mobility of the NMOS device. In addition, a direct contact between the high-k gate dielectric and the semiconductor substrate will produce a larger number of interface states, which will also degrade the carrier mobility, especially the electron mobility. As a result, the carrier mobility of the NMOS device will be greatly influenced.

Therefore, there is a need to provide a CMOSFET device with optimized structure and a fabrication method thereof to solve the problem of EOT reduction and carrier mobility degradation.

### SUMMARY OF THE INVENTION

In view of the above-mentioned problem, the present invention provides a semiconductor device comprising a semiconductor substrate having an NMOS region and a PMOS region which are isolated from each other, a first gate stack formed on the semiconductor substrate in the NMOS region, and a second gate stack formed on the semiconductor substrate in the PMOS region. The first gate stack comprises a first interface layer, a first high-k gate dielectric layer formed on the first interface layer, and a first gate layer formed on the first high-k gate dielectric layer, said first gate layer has one or more layers. The second gate stack comprises a second high-k gate dielectric layer, and a second gate layer formed on the second high-k gate dielectric layer, said second gate layer has one or more layers. The first interface layer is formed of one selected from the group consisting of SiO₂ and SiON_{X}. The first interface layer has a thickness of about 0.2-1.0 nm, preferably about 0.2-0.8 nm, and most preferably about 0.2-0.7 nm.

The present invention further provides a semiconductor device comprising a semiconductor substrate having an NMOS region and a PMOS region which are isolated from each other, a first gate stack formed on the semiconductor substrate in the NMOS region and a second gate stack formed on the semiconductor substrate in the PMOS region. The first gate stack comprises a first interface layer, a first high-k gate dielectric layer formed on the first interface layer, and a first gate layer formed on the first high-k gate dielectric layer, said first gate layer has one or more layers. The second gate stack comprises a second interface layer, a second high-k gate dielectric layer formed on the second interface layer, and a second gate layer formed on the second high-k gate dielectric layer, said second gate layer has one or more layers. The second interface layer has a dielectric constant higher than that of the first interface layer. The first interface layer is formed of one selected from the group consisting of SiO₂ and SiON_{X}. The first interface layer has a thickness of about 0.2-1.0 nm, preferably about 0.2-0.8 nm, and most preferably about 0.2-0.7 nm. The second interface layer is formed of one selected from the group consisting of AlN_{X}, Si₃N₄, SiON_{X}, HfAlO_{X}, HfZrO_{X}, HfSiO_{X} and a combination thereof. The second interface layer has a thickness of about 0.2-2 nm, preferably about 0.2-1 nm, and most preferably about 0.2-0.7 nm.

With the device structure of the present invention, the NMOS region and the PMOS region of the semiconductor substrate use interface layers of different thicknesses or different materials, which not only effectively reduces EOT of the device, especially EOT of the PMOS device, but also increases the electron mobility of the device, especially the electron mobility of the NMOS device, thereby effectively improving the overall performance of the device.

### BRIEF DESCRIPTION OF THE DRAWINGS

FIG. 1 schematically illustrates the structure of the semiconductor device according to a first embodiment of the present invention;

FIGS. 2-9 schematically illustrate the respective fabrication stages of the semiconductor device of the first embodiment of the present invention;

FIG. 10 schematically illustrates the structure of the semiconductor device according to a second embodiment of the present invention;

FIGS. 11-18 schematically illustrate the respective fabrication stages of the semiconductor device of the second embodiment of the present invention.

### DETAILED DESCRIPTION OF THE INVENTION

The present invention relates to a semiconductor device. The following disclosure provides many different embodiments or examples for realizing different structures of the present invention. To simplify the disclosure of the present invention, the components and configuration of specific examples are described in the following text. Of course, they are merely examples and are not intended to limit the invention. In addition, reference numerals and/or letters can be repeated in different examples in the present invention, and such repetition is for the purpose of concision and clarity, which in itself does not discuss the relationship between the various embodiments and/or configurations. Furthermore, the present invention provides examples of various specific techniques and materials, but those skilled in the art will be aware of the applicability of other techniques and/or materials. Moreover, the structure in which the first element is “above” the second element as described below may include the embodiment where the first and second elements are formed to be in direct contact, or it may also include the embodiment where a further element is formed between the first and second elements, in which case the first and second elements may not be in direct contact.

First Embodiment

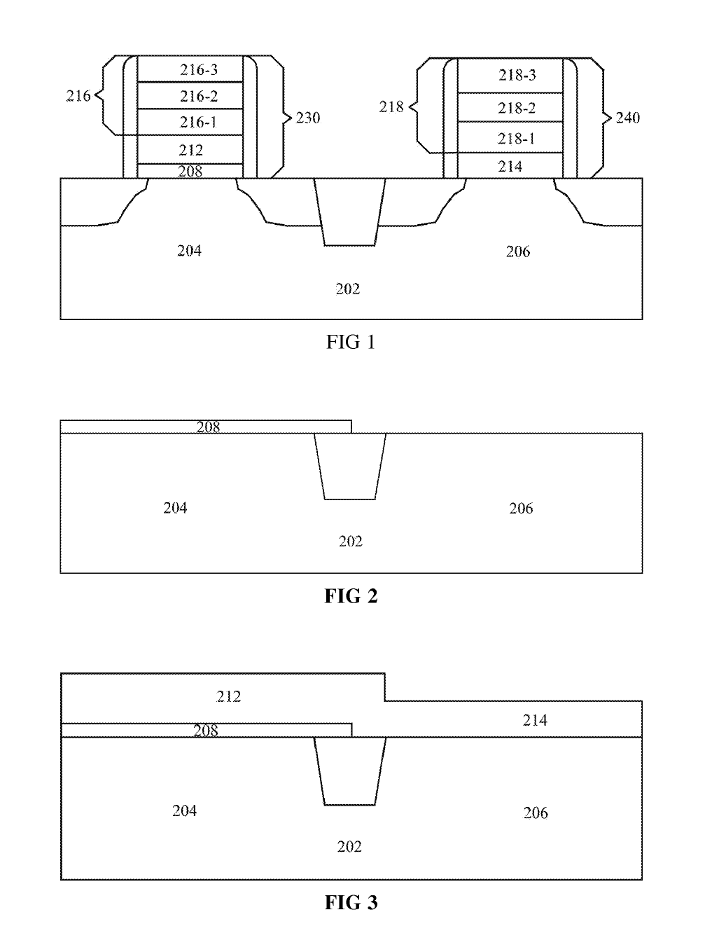

Reference is now made to FIG. 1. FIG. 1 schematically shows the structure of the semiconductor device according to an embodiment of the present invention. As shown in FIG. 1, the device comprises a semiconductor substrate 202 having an NMOS region 204 and a PMOS region 206 which are isolated from each other, a first gate stack 230 formed on the semiconductor substrate 202 in the NMOS region 204 and a second gate stack 240 formed on the semiconductor substrate 202 in the PMOS region 206. The first gate stack 230 comprises a first interface layer 208, a first high-k gate dielectric layer 212 formed on the first interface layer 208, and a first gate layer 216 formed on the first high-k gate dielectric layer 212 and having one or more layers. The second gate stack 240 comprises a second high-k gate dielectric layer 214 and a second gate layer 218 formed on the second high-k gate dielectric layer 214 and having one or more layers. The fabrication and implementation of said embodiment will be described in detail below.

As shown in FIG. 2, a first interface layer 208 is formed on the semiconductor substrate 202 in the NMOS region 204. The first interface layer 208 may be directly formed on the substrate 202. In this embodiment, the first interface layer 208 is formed of materials containing no or little elements that affects the electron mobility, such as Si rich SiON_{X}. Si rich SiON_{X} means that the content of Si is higher than the content of N. The first interface layer 208 has a thickness of about 0.2-1.0 nm, preferably about 0.2-0.8 nm, and most preferably about 0.2-0.7 nm. In this embodiment, the first interface layer 208 of SiON_{X} is formed by first oxidating the substrate 202 with nitrogen oxide (NO_{X}) or oxygen (O₂) or ozone (O₃), and then nitriding the substrate. This is only an example instead of a limitation. The first interface layer 208 may also be formed of SiO₂. The first interface layer 208 contains no or as less as possible elements that will degrade the electron mobility, such as SiO₂ and Si rich SiON_{X}. No interface layer is formed on the semiconductor substrate 202 in the PMOS region 206, so that the interface layer of the NMOS device may alleviate degradation of the electron mobility in the channel, meanwhile, EOT of the PMOS device is sufficiently reduced.

Afterwards, as shown in FIG. 3, a first high-k gate dielectric layer 212 is formed on the first interface layer 208, and a second high-k gate dielectric layer 214 is formed on the semiconductor substrate 202 in the PMOS region 206. Materials used for the first high-k gate dielectric layer 212 and second high-k gate dielectric layer 214 may include HfLaON_{X}, HfSiO_{X}, HfZrO_{X}, HfON, HfSiON, HfAlO_{X}, Al₂O₃, ZrO₂, ZrSiO_{X}, Ta₂O₅, La₂O₃, HfLaO_{X}, LaAlO_{X}, LaSiO_{X}, nitrides of said materials, oxynitrides of said materials, oxides of other rare earth elements and nitrides of other rare earth elements. The first high-k gate dielectric layer 212 and second high-k gate dielectric layer 214 can be deposited by sputtering, PLD, MOCVD, ALD, PEALD or other appropriate methods.

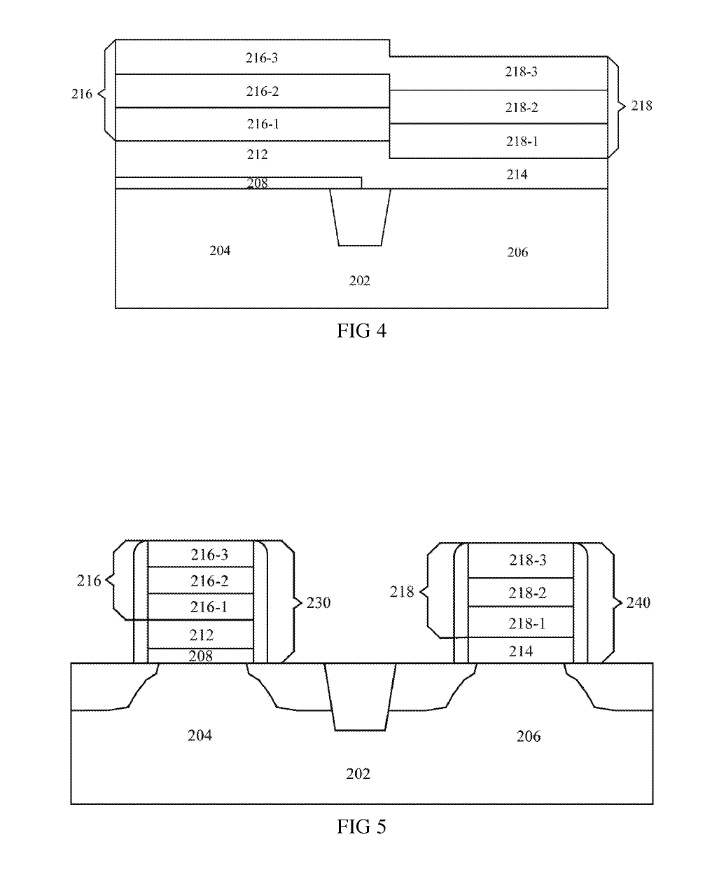

Then, as shown in FIG. 4, a first gate layer 216 is formed on the first high-k gate dielectric layer 212, and a second gate layer 218 is formed on the second high-k gate dielectric layer 214. The first gate layer 216 may include one or more material layers, and may be formed by depositing one or more species selected from the group consisting of TaC, HfC, TiC, TiN, TaTbN, TaErN, TaYbN, TaSiN, HfSiN, MoSiN, RuTa_{X}, NiTa_{X}, polysilicon, metal silicide, and a combination thereof. In this embodiment, the first gate layer 216 has a three-layered structure, in which a first work function metal layer 216-1 of TaC, a first metal gate layer 216-2 of TiN, and a first polysilicon layer 216-3 of polysilicon are deposited in this order on the first high-k gate dielectric layer 212. The second gate layer 218 may include one or more material layers, and may be formed by depositing one or more species selected from the group consisting of TaN, TaC_{X}, TiN, MoN_{X}, TiSiN, TiCN, TaAlC, TiAlN, PtSi_{X}, Ni₃Si, Pt, Ru, Ir, Mo, HfRu, RuO_{X}, polysilicon, metal silicide, and a combination thereof. In this embodiment, the second gate layer 218 has a three-layered structure, in which a second work function metal layer 218-1 of TaN, a second metal gate layer 218-2 of TiN, and a second polysilicon layer 218-3 of polysilicon are deposited in this order on the second high-k gate dielectric layer 214. The first gate layer 216 and the second gate layer 218 can be deposited by sputtering, PLD, MOCVD, ALD, PEALD or other appropriate methods. But this is only an example instead of a limitation.

Finally, as shown in FIG. 5, the previously formed laminated layers are patterned to form a gate stack 230 of the NMOS device and a gate stack 240 of the PMOS device. The formation of the gate stack 230 and the gate stack 240 can be realized by performing photolithography on the previously formed laminated layers once or several times. As a result, the semiconductor device according to the first embodiment of the present invention is obtained.

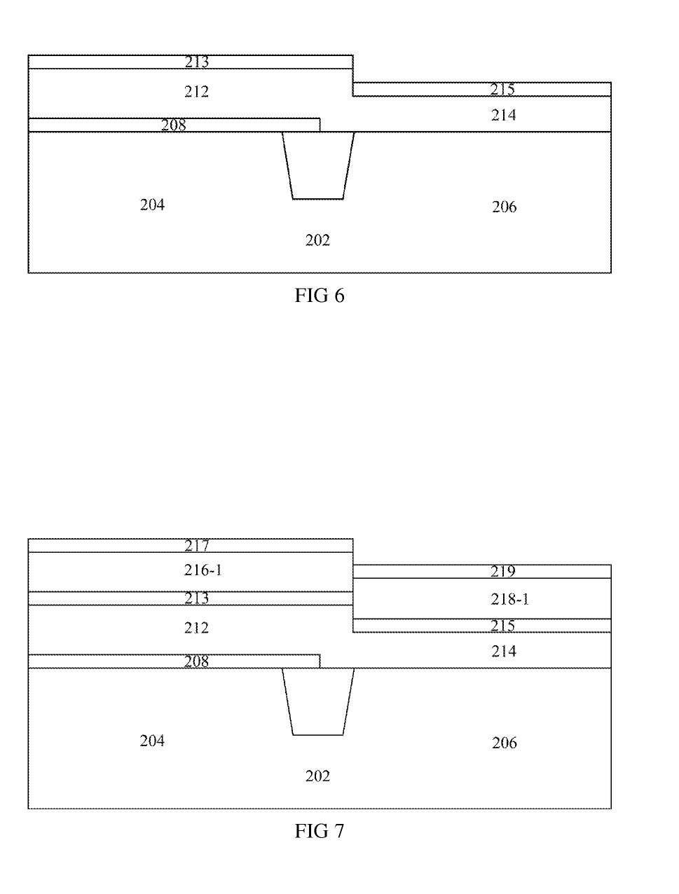

Preferably, as shown in FIG. 6, after forming the first high-k gate dielectric layer 212, a first high-k capping layer 213 can be optionally deposited thereon, and after forming the second high-k gate dielectric layer 214, a second high-k capping layer 215 can be optionally deposited thereon. The first high-k capping layer 213 has a thickness of about 0.1-3 nm, preferably about 0.5-2 nm, and most preferably about 0.5-1 nm. The material used for the first high-k capping layer 213 may include BeO_{X}, La₂O₃, Y₂O₃, Sc₂O₃, Dy₂O₃, Gd₂O₃, and other rare earth metal oxides, etc. The second high-k capping layer 215 has a thickness of about 0.1-3 nm, preferably about 0.5-2 nm, and most preferably about 0.5-1 nm. The material used for the second high-k capping layer 215 may include Al₂O₃, TiO_{X}, MgO₂, HfAlO_{X}, etc. The first high-k capping layer 213 and the second high-k capping layer 215 can be deposited by sputtering, PLD, MOCVD, ALD, PEALD or other appropriate methods. Providing the first high-k capping layer 213 and the second high-k capping layer 215 can effectively adjust the threshold voltage of the device.

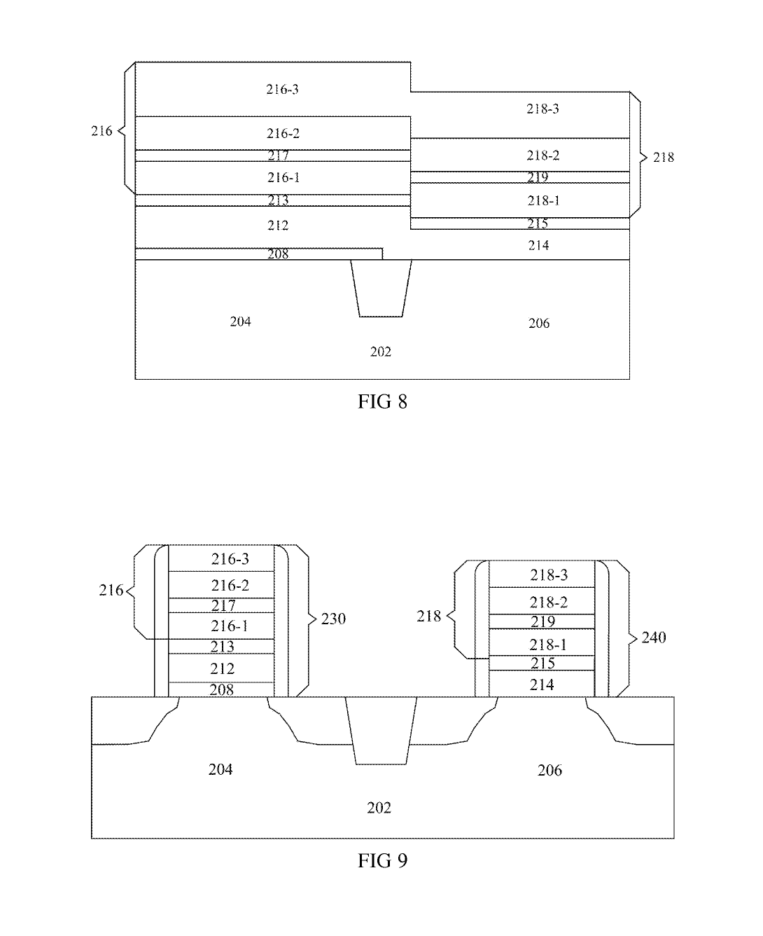

Preferably, as shown in FIG. 7, a first metal oxygen absorption layer 217 can be optionally deposited between layers of the first multiple-layered gate layer 216, and a second metal oxygen absorption layer 219 can be optionally deposited between layers of the second multiple-layered gate layer 218. The first metal oxygen absorption layer 217 and second metal oxygen absorption layer 219 may have a thickness ranging from about 1 nm to about 20 nm. Materials used for the first metal oxygen absorption layer 217 and the second metal oxygen absorption layer 219 may include Ta, Ti, Be, Al, Hf, Co and Ni. In this embodiment, as an example, rather than a limitation, the first metal oxygen absorption layer 217 of Ta is deposited on the first work function metal layer 216-1, and the second metal oxygen absorption layer 219 of Ta is deposited on the second work function metal layer 218-1. The first metal oxygen absorption layer 217 and the second metal oxygen absorption layer 219 are used to absorb the oxygen produced during the high temperature thermal process of the device so as to reduce EOT. Formation of other layers thereafter is as shown in FIG. 8 and FIG. 9, and the specific steps thereof which are just as the steps described above will not be illustrated for the purpose of concision.

Those skilled in the art should understand that the above preferred embodiment, in which the first high-k capping layer 213 and the first metal oxygen absorption layer 217 as well as the second high-k capping layer 215 and the second metal oxygen absorption layer 219 may be optionally provided in the first gate stack 230 and the second gate stack 240 as required by a design, is merely a preferred embodiment of the present invention, and should not be construed as limiting the invention. Those skilled in the art can configure and arrange the respective features of the device as required by a design without departing from the protection scope of the present invention.

The above only describes the method and device for alleviating the degradation of the carrier mobility of the NMOS device while continuously reducing EOT of the

PMOS device. The device according to the first embodiment of the present invention reduces EOT of the PMOS device and avoids significant degradation of the carrier mobility of the NMOS device, thereby effectively improving the overall performance of the device, because it only forms a first interface layer of, such as SiO₂ and Si rich SiON_{X}, on the NMOS region 204 of the semiconductor substrate, said first interface layer has little influence on the degradation of the electron mobility, and it makes the high-k gate dielectric directly contact the semiconductor substrate in the PMOS region 206, i.e. forming no interface layer.

Second Embodiment

The second embodiment of the present invention is described below. In the second embodiment, different interface layers are provided for the NMOS device and the PMOS device so as to adjust the carrier mobility of the NMOS device and the PMOS device, respectively.

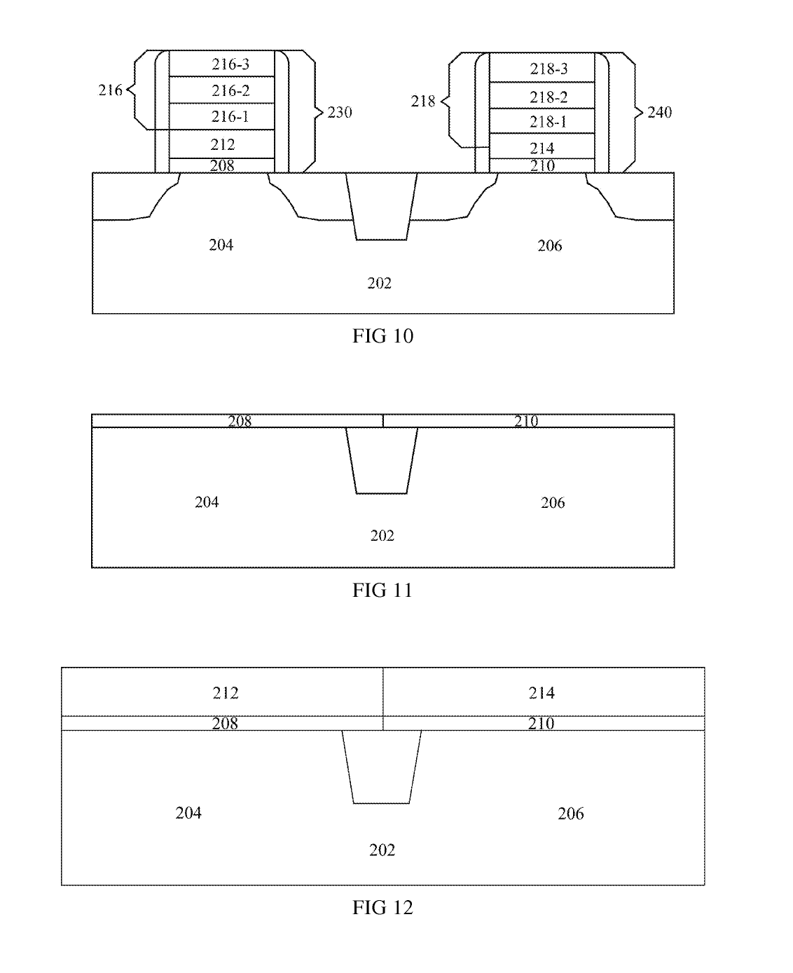

Reference is now made to FIG. 10. FIG. 10 schematically shows the structure of the semiconductor device according to the second embodiment of the present invention. As shown in FIG. 10, the device comprises a semiconductor substrate 202 having an NMOS region 204 and a PMOS region 206 which are isolated from each other, a first gate stack 230 formed on the semiconductor substrate 202 in the NMOS region 204 and a second gate stack 240 formed on the semiconductor substrate 202 in the PMOS region 206. The first gate stack 230 comprises a first interface layer 208, a first high-k gate dielectric layer 212 formed on the first interface layer 208, and a first gate layer 216 formed on the first high-k gate dielectric layer 212 and having one or more layers. The second gate stack 240 comprises a second interface layer 210, a second high-k gate dielectric layer 214 formed on the second interface layer 210, and a second gate layer 218 formed on the second high-k gate dielectric layer 214 and having one or more layers. The second interface layer 218 has a dielectric constant higher than that of the first interface layer 216. The fabrication and implementation of said embodiment will be described in detail below.

As shown in FIG. 11, a first interface layer 208 is formed on the semiconductor substrate 202 in the NMOS region 204, and a second interface layer 210 is formed on the semiconductor substrate in the PMOS region. In this embodiment, the first interface layer 208 is formed of materials containing no or little elements that affects the electron mobility, such as Si rich SiON_{X}. Alternatively, the first interface layer 208 can also be formed of SiO₂. The first interface layer 208 has a thickness of about 0.2-1.0 nm, preferably about 0.2-0.8 nm, and most preferably about 0.2-0.7 nm. In this embodiment, the substrate 202 is first oxidated by nitrogen oxide (NO_{X}) or oxygen (O₂) or ozone (O₃), and then subjected to a nitriding process to form Si rich SiON_{X} as the first interface layer 208. Said Si rich SiON_{X} means that the content of Si is higher than the content of N. This is only an example instead of a limitation.

The dielectric constant of the second interface layer 210 is higher than that of the first interface layer. Preferably, the relative dielectric constant of the first interface layer may be within the range of about 3.9-8, and the relative dielectric constant of the second interface layer may be within the range of 5-16. For example, the second interface layer 210 may be formed by AlN_{X} or by other materials, such as AlN_{X}, Si₃N₄, SiON_{X}, HfAlO_{X}, HfZrO_{X}, HfSiO_{X} or a combination thereof. The second interface layer 210 may has a thickness ranging from about 0.2 nm to about 2 nm, preferably from about 0.2 nm to 1 nm, and most preferably from about 0.2 nm to 0.7 nm. The second interface layer 210 may be implemented by physical or chemical method, such as atomic layer deposition, chemical vapor deposition (CVD), high density plasma CVD, sputtering or other appropriate methods.

The first interface layer 208 contains no or as less as possible elements that will degrade the electron mobility, such as SiO₂ and Si rich SiON_{X}. The second interface layer 210 contains compounds of elements, such as N, Al, and Hf, etc, that can effectively increase the dielectric constant of the interface layer without significantly degrading the hole carrier mobility. Such kind of asymmetric interface layers not only reduce EOT of the PMOS device but also alleviate degradation of the carrier mobility of the NMOS device.

Afterwards, as shown in FIG. 12, a first high-k gate dielectric layer 212 is formed on the first interface layer 208, and a second high-k gate dielectric layer 214 is formed on the second interface layer 210. Materials used for the first high-k gate dielectric layer 212 and second high-k gate dielectric layer 214 may include HfLaON, HfSiO_{X}, HfZrO_{X}, HfON, HfSiON, HfAlO_{X}, Al₂O₃, ZrO₂, ZrSiO_{X}, Ta₂O₅, La₂O₃, HfLaO_{X}, LaAlO_{X}, LaSiO_{X}, nitrides of said materials, oxynitrides of said materials, oxides of other rare earth elements and nitrides of other rare earth elements. The first high-k gate dielectric layer 212 and second high-k gate dielectric layer 214 can be deposited by sputtering, PLD, MOCVD, ALD, PEALD or other appropriate methods.

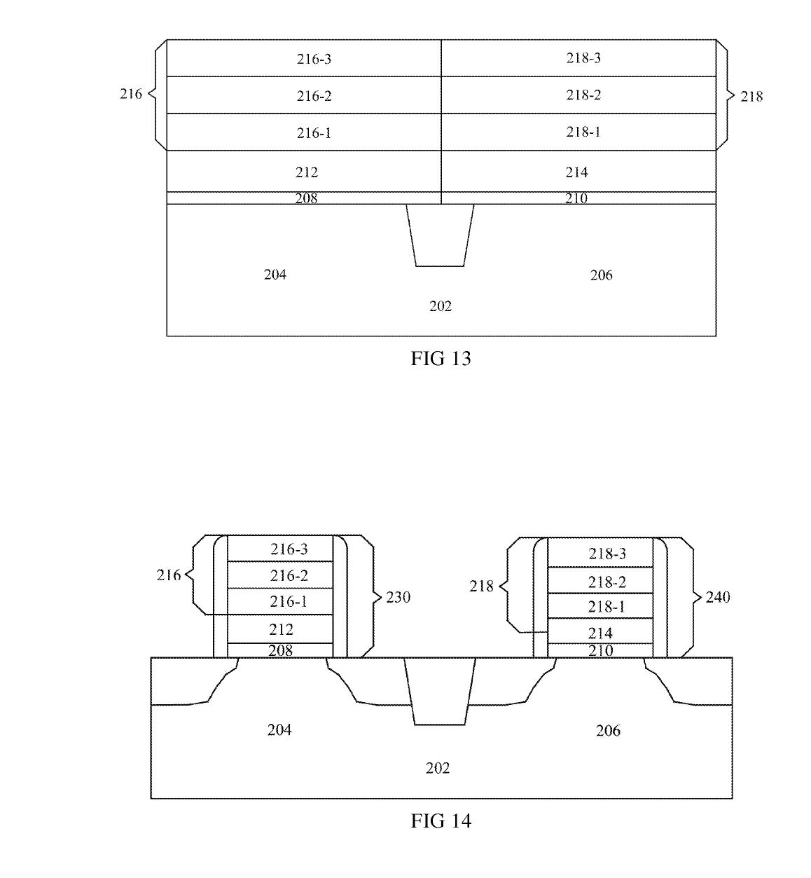

Then, as shown in FIG. 13, a first gate layer 216 is formed on the first high-k gate dielectric layer 212, and a second gate layer 218 is formed on the second high-k gate dielectric layer 214. The first gate layer 216 may include one or more material layers, and may be formed by depositing one or more species selected from the group consisting of TaC, HfC, TiC, TiN, TaTbN, TaErN, TaYbN, TaSiN, HfSiN, MoSiN, RuTa_{X}, NiTa_{X}, polysilicon, metal silicide, and a combination thereof. In this embodiment, the first gate layer 216 has a three-layered structure, in which a first work function metal layer 216-1 of TaC, a first metal gate layer 216-2 of TiN, and a first polysilicon layer 216-3 of polysilicon are deposited in this order on the first high-k gate dielectric layer 212. The second gate layer 218 may include one or more material layers, and may be formed by depositing one or more species selected from the group consisting of TaN, TaC_{X}, TiN, MoN_{X}, TiSiN, TiCN, TaAlC, TiAlN, PtSi_{X}, Ni₃Si, Pt, Ru, Ir, Mo, HfRu, RuO_{X}, polysilicon, metal silicide, and a combination thereof. In this embodiment, the second gate layer 218 has a three-layered structure, in which a second work function metal layer 218-1 of TaN, a second metal gate layer 218-2 of TiN, and a second polysilicon layer 218-3 of polysilicon are deposited in this order on the second high-k gate dielectric layer 214. The first gate layer 216 and the second gate layer 218 can be deposited by sputtering, PLD, MOCVD, ALD, PEALD or other appropriate methods. But this is only an example instead of a limitation.

Finally, as shown in FIG. 14, the previously formed laminated layers are patterned to form a gate stack 230 of the NMOS device and a gate stack 240 of the PMOS device. The gate stack 240 can be formed by performing photolithography process on the previously formed laminated layers once or several times. As a result, the semiconductor device according to the second embodiment of the present invention is obtained.

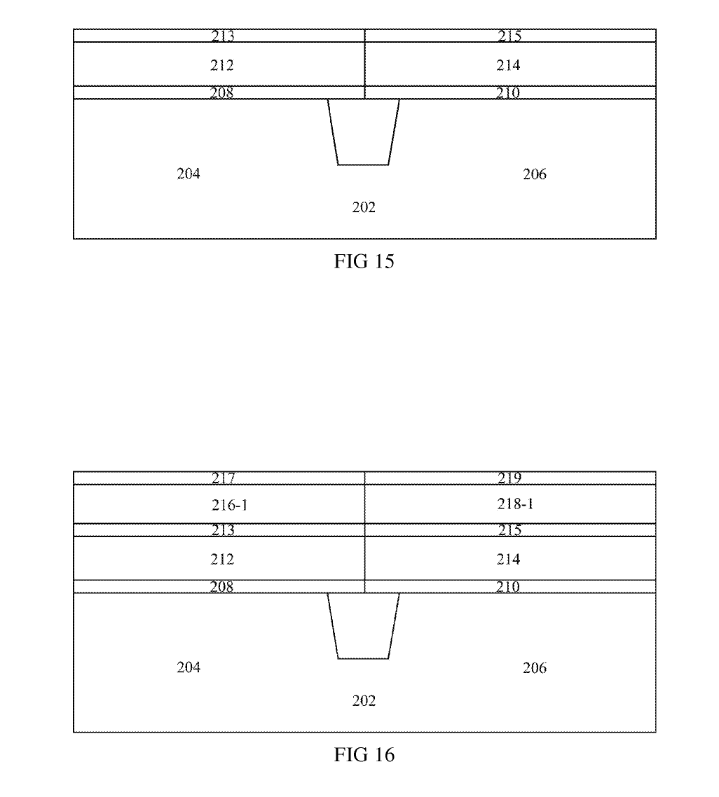

Preferably, as shown in FIG. 15, after forming the first high-k gate dielectric layer 212, a first high-k capping layer 213 can be optionally deposited thereon, and after forming the second high-k gate dielectric layer 214, a second high-k capping layer 215 can be optionally deposited thereon. The first high-k capping layer 213 has a thickness of about 0.1-3 nm, preferably about 0.5-2 nm, and most preferably about 0.5-1 nm. The material used for the first high-k capping layer 213 may include BeO_{X}, La₂O₃, Y₂O₃, Dy₂O₃, Sc₂O₃, Gd₂O₃, and other rare earth metal oxides, etc. The second high-k capping layer 215 has a thickness of about 0.1-3 nm, preferably about 0.5-2 nm, and most preferably about 0.5-1 nm. The material used for the second high-k capping layer 215 may include Al₂O₃, TiO₂, MgO₂ and HfAlO_{X}. The first high-k capping layer 213 and the second high-k capping layer 215 can be deposited by sputtering, PLD, MOCVD, ALD, PEALD or other appropriate methods. Providing the first high-k capping layer 213 and the second high-k capping layer 215 can effectively adjust the threshold voltage of the device.

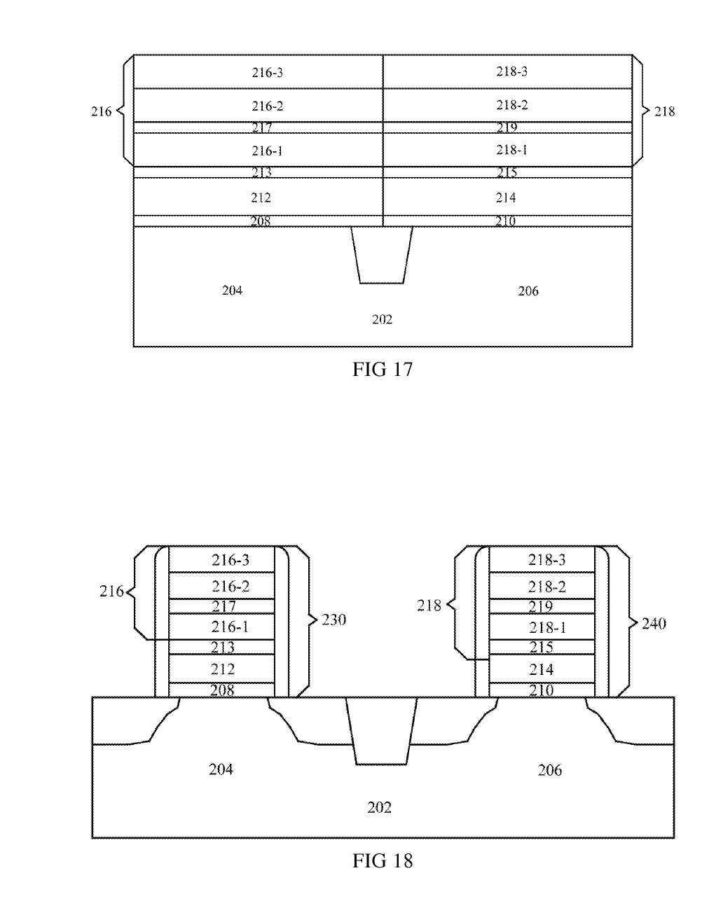

Preferably, as shown in FIG. 16, a first metal oxygen absorption layer 217 can be optionally deposited between layers of the first multiple-layered gate layer 216, and a second metal oxygen absorption layer 219 can be optionally deposited between layers of the second multiple-layered gate layer 218. The first metal oxygen absorption layer 217 and second metal oxygen absorption layer 219 may have a thickness within the range of about 1 nm to about 20 nm. Materials used for the first metal oxygen absorption layer 217 and the second metal oxygen absorption layer 219 may include Ta, Ti, Be, Al, Hf, Co and Ni. In this embodiment, as an example, rather than a limitation, the first metal oxygen absorption layer 217 of Ta is deposited on the first work function metal layer 216-1, and the second metal oxygen absorption layer 219 of Ta is deposited on the second work function metal layer 218-1. The first metal oxygen absorption layer 217 and the second metal oxygen absorption layer 219 are used to absorb the oxygen produced during the high temperature thermal processing of the device so as to reduce EOT. Formation of other layers thereafter is as shown in FIG. 17 and FIG. 18, and the specific steps thereof which are just as the steps described above will not be illustrated for the purpose of concision.

Those skilled in the art should understand that the above preferred embodiment, in which the first high-k capping layer 213 and the first metal oxygen absorption layer 217 as well as the second high-k capping layer 215 and the second metal oxygen absorption layer 219 may be optionally provided in the first gate stack 230 and the second gate stack 240 as required by a design, is merely a preferred embodiment of the present invention, and should not be construed as limiting the invention. Those skilled in the art can configure and arrange the respective features of the device as required by a design without departing from the protection scope of the present invention.

The above only describes the method and device for alleviating the degradation of the carrier mobility of the NMOS device while continuously reducing EOT of the PMOS device. In the device according to the second embodiment of the present invention, insulating interface layers of different materials can be formed on the substrate in the NMOS region and the PMOS region. A first interface layer 208 is formed of for example SiO₂ and Si rich SiON_{X} on the semiconductor substrate in the NMOS region 204, and has little influence on the degradation of the electron mobility. A second interface layer 210 is formed in the PMOS region 206, and contains compounds of elements that can effectively increase the dielectric constant of the interface layer without significantly degrading the hole carrier mobility, and has a dielectric constant higher than that of the first interface layer 208 of the NMOS device. Thus, the EOT of the PMOS device can be reduced and significant degradation of the carrier mobility of the NMOS device can be avoided. As a result, the overall performance of the devices is effectively improved.

Although the example embodiments and the advantages thereof have been described in detail, it shall be understood that various changes, substitutions and modifications can be made to said embodiments without departing from the spirit of the invention and the protection scope defined by the appended claims. As for other examples, those ordinarily skilled in the art shall easily understand that the sequence of the process steps may be changed without departing from the protection scope of the present invention.

In addition, the application of the present invention is not limited to the techniques, mechanisms, fabrication, compositions, means, methods and steps in the specific embodiments described in the description. On the basis of the disclosure of the present invention, those ordinarily skilled in the art shall easily understand that the existing or to be developed techniques, mechanisms, fabrication, compositions, means, methods and steps, which have substantially the same function or achieve substantially the same effect as the respective embodiments described in the present invention, can also be used according to the present invention. Therefore, the appended claims intend to include such techniques, mechanisms, fabrication, compositions, means, methods and steps in the protection scope thereof.

What is claimed is:

1. A semiconductor device, comprising:
a semiconductor substrate having an NMOS region and a PMOS region, said NMOS region and said PMOS region being isolated from each other;
a first gate stack formed on the semiconductor substrate in the NMOS region and a second gate stack formed on the semiconductor substrate in the PMOS region;
wherein the first gate stack comprises a first interface layer, a first high-k gate dielectric layer formed on the first interface layer, a first gate layer formed on the first high-k gate dielectric layer, wherein the first gate layer has one or more layers, and the first interface layer is formed of materials containing no or little elements that influence the electron mobility;
the second gate stack comprises a second interface layer, a second high-k gate dielectric layer, a second gate layer formed on the second high-k gate dielectric layer, wherein the second gate layer has one or more layers.

2. The device according to claim 1, wherein the first interface layer is formed of one selected from the group consisting of SiO₂ and Si rich SiON_{X}.

3. The device according to claim 1, further comprising a first high-k capping layer formed on the first high-k gate dielectric layer, and a second high-k capping layer formed on the second high-k gate dielectric layer.

4. The device according to claim 3, wherein the first high-k capping layer is formed of one selected from the group consisting of BeO_{X}, La₂O₃, Y₂O₃, Sc₂O₃, Dy₂O₃, Gd₂O₃, other rare earth metal oxides, and a combination thereof.

5. The device according to claim 3, wherein the second high-k capping layer is formed of one selected from the group consisting of Al₂O₃, TiO₂, MgO₂, TiO₂, HfAlO_{X}, and a combination thereof.

6. The device according to claim 1, further comprising a first metal oxygen absorption layer located between layers of the first multiple-layered gate, and a second metal oxygen absorption layer located between layers of the second multiple-layered gate layer.

7. The device according to claim 6, wherein the first and second metal oxygen absorption layers are formed of an element selected from the group consisting of Ta, Ti, Be, Al, Hf, Co and Ni.

8. A semiconductor device, comprising:
a semiconductor substrate having an NMOS region and a PMOS region, said NMOS region and said PMOS region being isolated from each other;
a first gate stack formed on the semiconductor substrate in the NMOS region and a second gate stack formed on the semiconductor substrate in the PMOS region;
wherein the first gate stack comprises a first interface layer, a first high-k gate dielectric layer formed on the first interface layer, and a first gate layer formed on the first high-k gate dielectric layer, wherein the first gate layer has one or more layers;
the second gate stack comprises a second interface layer, a second high-k gate dielectric layer formed on the second interface layer, and a second gate layer formed on the second high-k gate dielectric layer, wherein the second gate layer has one or more layers;
wherein the first interface layer is formed of materials containing no or little elements that influence the electron mobility, and the second interface layer has a dielectric constant higher than that of the first interface layer.

9. The device according to claim 8, wherein the first interface layer is formed of one selected from the group consisting of SiO₂ and Si rich SiON_{X}.

10. The device according to claim 8, wherein the second interface layer is formed of one selected from the group consisting of AlN_{X}, Si₃N₄, SiON_{X}, HfAlO_{X}, HfZrO_{X}, HfSiO_{X}, and a combination thereof.

11. The device according to claim 8, wherein the first interface layer has a relative dielectric constant which ranges from about 3.9 to 8.

12. The device according to claim 8, wherein the second interface layer has a relative dielectric constant which ranges from about 5 to 16.

13. The device according to claim 8, further comprising a first high-k capping layer formed on the first high-k gate dielectric layer, and a second high-k capping layer formed on the second high-k gate dielectric layer.

14. The device according to claim 13, wherein the first high-k capping layer is formed of one selected from the group consisting of BeO_{X}, La₂O₃, Y₂O₃, Sc₂O₃, Dy₂O₃, Gd₂O₃, and other rare earth metal oxides, etc.

15. The device according to claim 13, wherein the second high-k capping layer is formed of one selected from the group consisting of Al₂O₃, TiO₂, MgO₂, TiO₂, HfAlO_{X}, and a combination thereof.

16. The device according to claim 8, further comprising: a first metal oxygen absorption layer located between layers of the first multiple-layered gate, and a second metal oxygen absorption layer located between layers of the second multiple-layered gate layer.

17. The device according to claim 16, wherein the first and second metal oxygen absorption layers are formed of an element selected from the group consisting of Ta, Be, Ti, Al, Hf, Co and Ni.
